(19) United States
(12) Patent Application Publication
(10) Pub. No.: US 2014/0374912 A1
(43) Pub. Date: Dec. 25, 2014

(54) Micro-Spring Chip Attachment Using Solder-Based Interconnect Structures

(71) Applicant: Palo Alto Research Center Incorporated, Palo Alto, CA (US)

(72) Inventor: John C. Knights, Soquel, CA (US)

(21) Appl. No.: 13/925,753

(22) Filed: Jun. 24, 2013

(51) Int. Cl. H01L 23/00

(52) U.S. Cl. CPC H01L 24/05; H01L 24/66; H01L 24/89
USPC 257/769; 257/779; 438/117

(57) ABSTRACT

Standard solder-based interconnect structures are utilized as mechanical fasteners to attach an IC die in a “flip-chip” orientation to a support structure (e.g., a package base substrate or printed circuit board). Electrical connections between the support structure and the IC die are achieved by curved micro-springs that are disposed in peripheral regions of the IC die and extend through a gap region separating the upper structure surface and the processed surface of the IC die. The micro-springs are fixedly attached to one of the support structure and the IC die, and have a free (tip) end that contacts an associated contact pad disposed on the other structure/IC die. Conventional solder-based connection structures (e.g., solder-bumps/balls) are disposed on “dummy” (non-functional) pads disposed in a central region of the IC die. After placing the IC die on the support structure, a standard solder reflow process is performed to complete the mechanical connection.

### FIELD OF THE INVENTION

This invention relates to integrated circuits, and is particularly applicable to integrated circuit die/substrate assemblies, and to method for mounting integrated circuit dies on support substrates, for example, to produce in packaged semiconductor devices.

### BACKGROUND OF THE INVENTION

The phrase “circuit assembly” refers both to an assembled/packaged electronic device/system and to the process of electrically and mechanically connecting one or more electronic components (e.g., a bare integrated circuit (IC) die or a packaged IC device) to a printed circuit support structure (e.g., a package substrate or a printed circuit board (PCB)) in a way that forms such electronic devices/systems. A semiconductor package is one type of circuit assembly including a metal, plastic, glass, or ceramic casing containing one or more “bare” semiconductor electronic components (typically referred to as IC die or “chips”) that performs a specified function (e.g., providing non-volatile memory or performing microprocessor functions). Individual discrete components are formed using known semiconductor fabrication techniques (e.g., CMOS) on silicon wafers, the wafers are then cut (diced) to form individual IC die, and then the IC die are the assembled in a package (e.g., mounted on a package substrate similar to a printed circuit board). The package provides protection against impact and corrosion, holds the contact pins or leads which are used to connect from external circuits to the device, and dissipates heat produced in the IC die. Other types of circuit assemblies include, for example, printed circuit board (PCB) assemblies, which typically include a large number of packaged IC devices and other components that are electrically and mechanically secured to a host PCB.

Currently, the process of assembling components into fully functional printed circuit boards and is universally dependent on the use of solder to make electrical connections. Because of environmental concerns, the solder, which used to contain lead, is now lead free with the consequence that the temperature at which the solder melts and reflows is significantly higher than that of the lead containing solder. This higher temperature means that, after the solder has solidified, the remaining temperature drop back to room temperature causes greater stress to build up due to the temperature coefficient of expansion (TCE) mismatch between components. This is a particular problem for components such as state of the art silicon VLSI devices, where the use of low-dielectric constant (low k) and strain engineered finer geometry devices have made the devices more susceptible to TCE-induced stress than prior generations. It is also the case that since the solder forms large area metal-metal bridges across the gap between components, that the assembled components are mechanically attached as well, sufficient to pass shock and vibration tests.

Micro-spring technology was recently developed to address the TCE-induced stress problems associated with lead-free solder connections. Micro-springs are batch-fabricated on a host substrate (i.e., either the IC die or the package base substrate), for example, using stress-engineered thin films that are sputter-deposited with a built-in stress gradient, and then patterned to form individual flat micro-spring structures having narrow finger-like portions extending from associated base (anchor) portions. The narrow finger-like portions are then released from the host substrate (the anchor portion remains attached to the substrate), whereby the built-in stress causes the finger-like portions to bend (curl) out of the substrate plane with a designed radius of curvature, whereby the tip end of the resulting curved micro-spring is held away from the host substrate. The host substrate is then mated with a corresponding structure such that the tip ends of the micro-springs abut corresponding metal contact pads, whereby the (electrically conductive) micro-spring interconnect structures facilitate electrical signal transmissions between the host substrate (e.g., an IC die) and a corresponding structure (e.g., a package base substrate). By compressing the chip and board together, pressure contacts are formed by the micro-springs which have been shown to pass the requisite JEDEC tests of temperature cycling and exposure to high humidity, thereby making micro-spring interconnect structures an attractive alternative to lead-free solder connections.

Current methods for securing two components that are electrically connected by micro-springs (e.g., securing IC dies to package base substrates) typically requires the use of an adhesive disposed in the narrow gap between the two components in order to maintain contact between the micro-springs and associated contact pads. Unfortunately, the required adhesive dispensing and curing processes are typically not employed by the companies that assemble printed circuit boards and packed IC devices in high volumes. The inclusion of the adhesive dispensing and curing processes thus presents a barrier to easy adoption of the micro-spring technology. In addition, adhesives cannot be used in some high reliability electronics packaging and military applications because of organic outgassing risks, which limit ultimate reliability.

One possible alternative technique for securing two components by micro-spring without adhesive is to secure the ends of the micro-springs by solder. In this approach, the micro-springs are formed on one component as described above, and solder paste is deposited on the associated second component in a manner similar to conventional solder-based assembly. During assembly, the free ends (tips) of the micro-springs are pushed into the solder paste, and then the assembly is subjected to a conventional reflow step. Unfortunately, although the electrical connections made by this method survive JEDEC temperature and humidity tests, adhesive is still required, e.g. corner bonds, to pass shock and vibration tests, which is problematic for the reasons provided above.

What is needed is a low-cost method for reliably securing two components (e.g., an IC die to a package support structure) using micro-springs that avoids the need for adhesives.

### SUMMARY OF THE INVENTION

The present invention is directed to a low-cost circuit assembly and associated circuit assembly method that utilizes both curved micro-spring interconnect structures (micro-springs) and one or more solder-based interconnect structure to electrically and mechanically secure a device (e.g., an integrated circuit (IC) die/chip, a packaged IC device, or a circuit element such as a light emitting diode (LED)) to a printed circuit support structure (e.g., a package substrate or a printed circuit board (PCB)). Specifically, the micro-spring connectors are deployed using existing micro-spring techniques to provide compliant electrical connections between the IC device and the support structure, and the one or more solder-based interconnect structure is formed using substantially conventional techniques to provide a rigid mechanical connection between the device and support. By combining the use of micro-spring and solder-based connections, the present invention provides a cost-effective solution to the problems associated with conventional attachment methods. First, by utilizing the solder-based interconnect structures solely for mechanical connection (i.e., by utilizing micro-springs to provide all or most of the electrical connections), the number of solder-based interconnect structures can be minimized, thereby minimizing the TCE-induced stress problems associated with solder-only interconnect schemes. Second, because the solder-based interconnect structures essentially “weld” the two components together, the resulting assembly is reliably secured without the need for adhesive, thereby avoiding the cost and other considerations currently hampering adoption of micro-spring interconnect technology. Third, because the final assembly process is essentially identical to conventional solder-based assembly processes, the circuit assembly method of the present invention facilitates an almost seamless transition from all-solder assembly processes to micro-spring interconnect technology. That is, the present invention allows circuit assemblers to utilize their existing (e.g., standard solder reflow) assembly equipment without adding any new steps to the assembly process, thereby providing their customers with circuit assemblies that incorporate the beneficial aspects of micro-spring technology along with reliable permanent rigid mechanical connections without increasing assembly costs.

In accordance with alternative embodiments of the present invention, the one or more solder-based interconnect structure is connected between the IC device and the support structure either by way of “dummy” contact pads (i.e., metal pads that do not form an electrical connection between the IC device and the support structure) or using “functional” contact pads. The “dummy” contact pads are formed simultaneously with “functional” contact pads (i.e., using the same design rules/sizes and materials as conventional contact pads associated with the micro-springs), but are electrically isolated from processed circuitry. In an alternative embodiment, the solder-based interconnect structures are formed between functional contact pads that transmit, for example, a ground potential between the associated components.

According to another embodiment of the present invention, the micro-spring interconnect structures are disposed in a peripheral area of the circuit assembly (i.e., adjacent to a peripheral edge of the device/component) and the one or more solder-based interconnect structure are located in a central area such that it is substantially surrounded by the micro-springs. By positioning the micro-springs around the periphery, whether the micro-springs are disposed to make pressure (solder-free) contact or be connected by way of solder, the micro-springs would not be placed under significant mechanical stress from vibration or shock. The “dummy” (contact pads (i.e., those used for the solder-based interconnect structures) are sized to facilitate maximum capillary forces that act in the molten solder to pull the associated components together (i.e. maximum perimeter length within some areal constraints). In one specific embodiment, several sets of “dummy” contact pads are located close to each other (e.g., clustered in a central region of the circuit assembly) in order to minimize the effects of TCE mismatch. In another specific embodiment, the “dummy” contact pads are laid out in a manner that maximizes the capillary forces that act in the molten solder to pull the components together (i.e. maximum perimeter length within some areal constraints).

According to yet another embodiment of the present invention, the solder-based interconnect structures are located such that they maximize heat conductance in the circuit assembly. For example, the solder-based interconnect structures may be positioned form a perimeter around a “hot spot” (region of high temperature) and thermally coupled to a material with a higher thermal conductivity (e.g., a material with a much lower melting point, such as indium) that is either deposited prior to reflow, or capillaried in subsequent to reflow to provide superior heat management.

### BRIEF DESCRIPTION OF THE DRAWINGS

These and other features, aspects and advantages of the present invention will become better understood with regard to the following description, appended claims, and accompanying drawings, where:

FIGS. 1(A) and 1(B) are cross-sectional side and top plan views showing an exemplary circuit assembly according to an embodiment of the present invention;

FIGS. 2(A), 2(B) and 2(C) are perspective views depicting an assembly method according to another embodiment of the present invention;

FIGS. 3(A) and 3(B) are cross-sectional side views showing a solder reflow process performed in accordance with FIGS. 2(B) and 2(C);

FIG. 4 is a top plan view showing an exemplary circuit assembly according to another embodiment of the present invention; and

FIG. 5 is a top plan view showing an exemplary circuit assembly according to yet another embodiment of the present invention.

### DETAILED DESCRIPTION OF THE DRAWINGS

The present invention relates to an improvement in semiconductor packaging and other semiconductor circuit assemblies. The following description is presented to enable one of ordinary skill in the art to make and use the invention as provided in the context of a particular application and its requirements. As used herein, directional terms such as “upper”, “upward”, “top”, “lower”, “downward”, and “side” are intended to provide relative positions for purposes of description, and are not intended to designate an absolute frame of reference. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

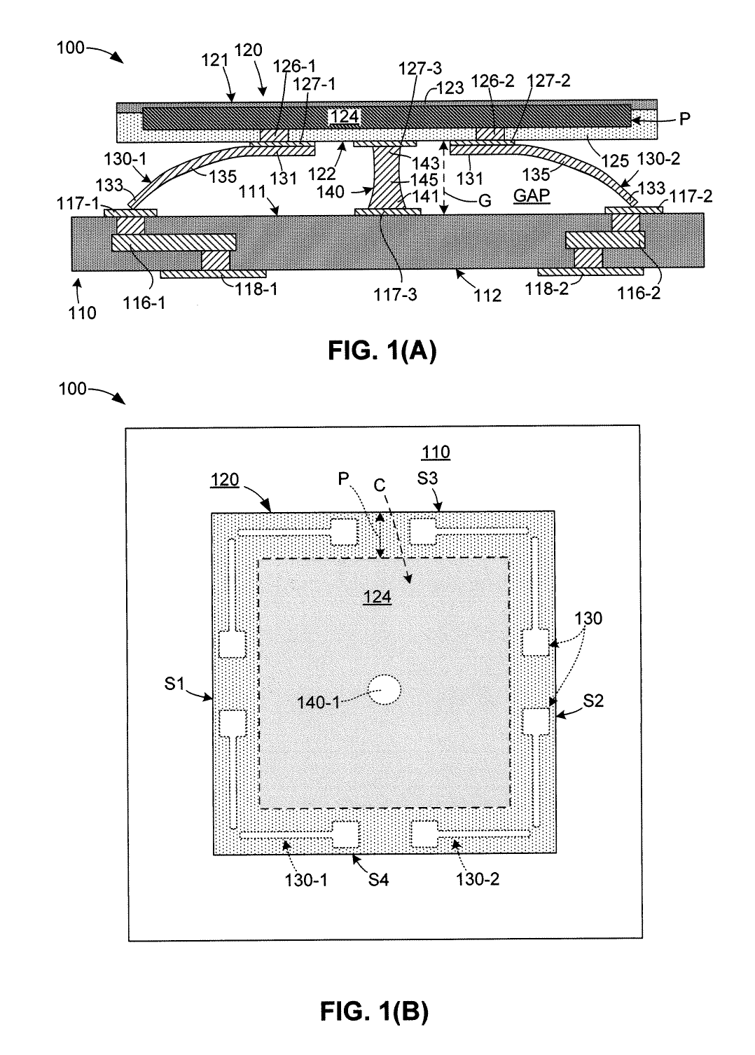

FIGS. 1(A) and 1(B) are cross-sectional side and top plan views showing a semiconductor package-type circuit assembly 100 according to a generalized and greatly simplified embodiment of the present invention. Circuit assembly 100 generally includes a package base substrate (support structure) 110, an integrated circuit (IC) die (IC device) 120, curved micro-springs 130 (e.g., micro-springs 130-1 and 130-2, which are shown in FIG. 1(A)), and a solder-based interconnect structure 140. Although only two micro-springs 130-1 and 130-2 are shown in FIG. 1(A) and eight micro-springs are shown in FIG. 1(B) in order to simplify the following description, several tens of micro-springs are typically utilized in practical applications to interconnect a functional support structure and an associated IC die, all of which being disposed and connected in the manner described below with reference to micro-spring 130.

Referring to the lower portion of FIG. 1(A), support structure 110 provides a package base structure onto which IC die 120 is mounted. Support structure 110 is a printed circuit board (PCB) formed by any suitable electrically non-conductive package base substrate (e.g., sapphire, ceramic, glass, or organic board material) that is fabricated using known techniques to provide conductive pathways for the transfer of electric signals between “support” contact pads formed on an upper surface 111 and lower surface 112. For example, a first signal path is established between upper (first support) contact pad 117-1 and a lower contact pad 118-1 by way of internal conductor 116-1 (i.e., metal plugs/vias and metal traces formed in and between the layers non-conductive material), and a second signal path is established between upper contact pad 117-2 and a lower contact pad 118-2 by way of internal conductor 116-2, whereby support structure 110 is suitably configured for use as a package base substrate.

In accordance with an embodiment of the present invention, support structure 110 also includes one or more electrically isolated “dummy” (non-functional) contact pads that are formed on an upper surface 111. For example, (second) support contact pad 117-3 is disposed on upper surface 111 such that it is electrically isolated from all conductors that form signal paths between upper surface 111 and lower surface 112. In a specific embodiment, “dummy” support contact pad 117-3 is formed by the same process used to form “functional” support contact pads 117-1 and 117-2 (i.e., the composition and thickness of “dummy” contact pad 117-3 is essentially identical to that of support contact pads 117-1 and 117-2). As described below, these “dummy” (non-functional) support contact pads serve a mechanical connection function, and as such may be formed by a modified PCB fabrication process that provides a more robust structure for providing a reliable mechanical connection.

Referring to the upper portion of FIG. 1(A), IC die 120 is a semiconductor device including an integrated circuit 124 formed on one surface of a semiconductor (e.g., silicon) “chip” 123 using any known semiconductor fabrication technique (e.g., CMOS). In such devices a passivation layer 125 is typically formed over integrated circuit 124, with metal interconnect structures extending through passivation layer 125 to “device” contact pads disposed on an external surface of IC die 120 (e.g., metal vias 126-1 and 126-2 extend through passivation layer 125 between integrated circuit 124 and contact pads 127-1 and 127-2, respectively). Because standard semiconductor fabrication techniques typically involve processing performed entirely on one side of semiconductor chip 123 and typically conclude with passivation and metallization, contact pads used to make electrical contact with integrated circuit 124 (e.g., contact pads 127-1 and 127-2) are disposed only on the outer surface of passivation layer 125, which is referred to as herein as “processed” (lower) surface 122 of IC die 120. The opposing surface of IC die 120 is referred to as the “unprocessed” surface 121 because there are typically no conductive paths disposed between unprocessed surface 121 and integrated circuit 124.

Similar to support structure 110, IC die 120 is fabricated to include one or more electrically isolated “dummy” device contact pads that are formed on passivation layer 125 and exposed on processed surface 122. For example, (second) device contact pad 127-3 is disposed on lower surface 122 such that it is electrically isolated by passivation material from integrated circuit 124 (i.e., no conductors form signal paths between device contact pad 127-3 and integrated circuit 124). “Dummy” device contact pad 127-3 is formed using the same metallization process utilized to form “functional” device contact pads 127-1 and 127-2, and serve the mechanical connection function described below.

According to an aspect of the present invention, IC die 120 is mounted on package substrate (support structure) 110 in a standard flip-chip orientation such that processed surface 122 faces upper surface 111 of package substrate 110. Note that the standard flip-chip orientation causes processed surface 122 to become the lower (downward-facing) surface of IC die 120 in the finished assembly, with unprocessed surface 121 forming the upper (upward facing) surface of IC die 120.

According to another aspect of the present invention, IC die 120 is electrically connected to support structure 110 by way of a curved micro-springs 130, and IC die 120 is mechanically connected to support structure 110 by way of one or more solder-based interconnect structure 140, wherein both micro-springs 130 solder-based interconnect structures 140 are disposed in a gap region GAP defined between processed surface 122 and upper substrate surface 111. In one embodiment, in addition to the presence of micro-springs 130 and solder-based interconnect structures 140, the entire remaining volume of gap region GAP is filled with air (i.e., micro-springs 130 and solder-based interconnect structures 140 extend through an air-filled gap region between IC die 120 and support structure 110.

Each curved micro-spring 130 (e.g., micro-springs 130-1 and 130-2, see FIG. 1(A)) is an integral structure having an anchor (first) end portion 131 that is fixedly connected to processed surface 122 and is electrically connected to contact pad 127, a tip/free end (second portion 133 that is in nonattached contact (i.e., not attached by way of solder or other adhesive) with contact pad 117, and curved body portion 135 extending between the first and second ends through the intervening air gap region. Each micro-spring 130 is at least partially composed of a spring metal (e.g., molybdenum (Mo), a “moly-chrome” alloy (MoCr), tungsten (W), a titanium-tungsten alloy (Ti:W), chromium (Cr), copper (Cu), nickel (Ni) and a nickel-zirconium alloy (NiZr)), and is produced such that body portion 135 resiliently flexes when tip/free end abuts contact pad 127, thereby providing and maintaining a reliable electrical connection between IC die 120 and support substrate 110.

As used herein, the phrase “solder-based interconnect structure” refers to any (preferably lead-free) solder connection structure utilized in semiconductor packaging or PCB assembly, such as structures formed from solder bumps, solder balls, and other solder-based structures typically utilized in standard reflow soldering processes. Lead-free solder material typically includes tin, copper and silver, and optionally include one or more of bismuth, indium, zinc, antimony, and traces of other metals. As indicated in FIG. 1(A), an exemplary solder-based interconnect structure 140 entirely comprises a lead-free solder material, and generally includes a lower (first) end portion 141 securely connected to the “dummy” support contact pad 117-3, an upper (second) end portion 143 securely connected to the “dummy” device contact pad 127-3, and a body portion 145 that extends between the upper and lower end portions and has sufficient size and strength to rigidly mechanically secure IC device 120 to support structure 110.

FIG. 1(B) shows circuit assembly 100 in top view, and shows that IC die 120 is a four-sided (square) structure (i.e., IC die 120 has a substantially four-sided peripheral edge formed by a first side S1, a second side S2, a third side S3 and a fourth side S4). In the present embodiment IC die 120 is mechanically secured to support substrate 110 solely by solder-based interconnect structure 140 by way of the “dummy” contact pads, and is electrically connected to support structure 110 solely by micro-springs 130 by way of the “functional” contact pads.

According to another aspect of the disclosed embodiment depicted in FIG. 1(B), micro-spring interconnect structures 130 are disposed in a peripheral area P of circuit assembly 100 (i.e., adjacent to one of peripheral side edges S1-S4 of IC die 120), and solder-based interconnect structure 140 is located in a central area C that is surrounded by peripheral area P. By positioning micro-springs 130 around the periphery of IC die 120, whether micro-springs 130 are disposed to make pressure (solder-free) contact or be connected by way of solder, they would not be placed under significant mechanical stress from vibration or shock.

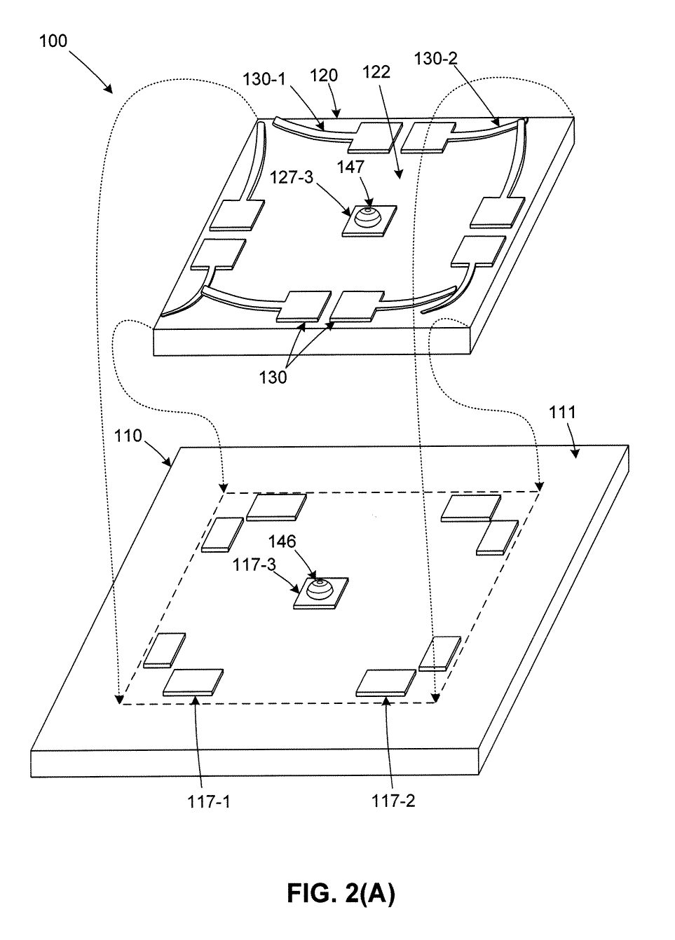

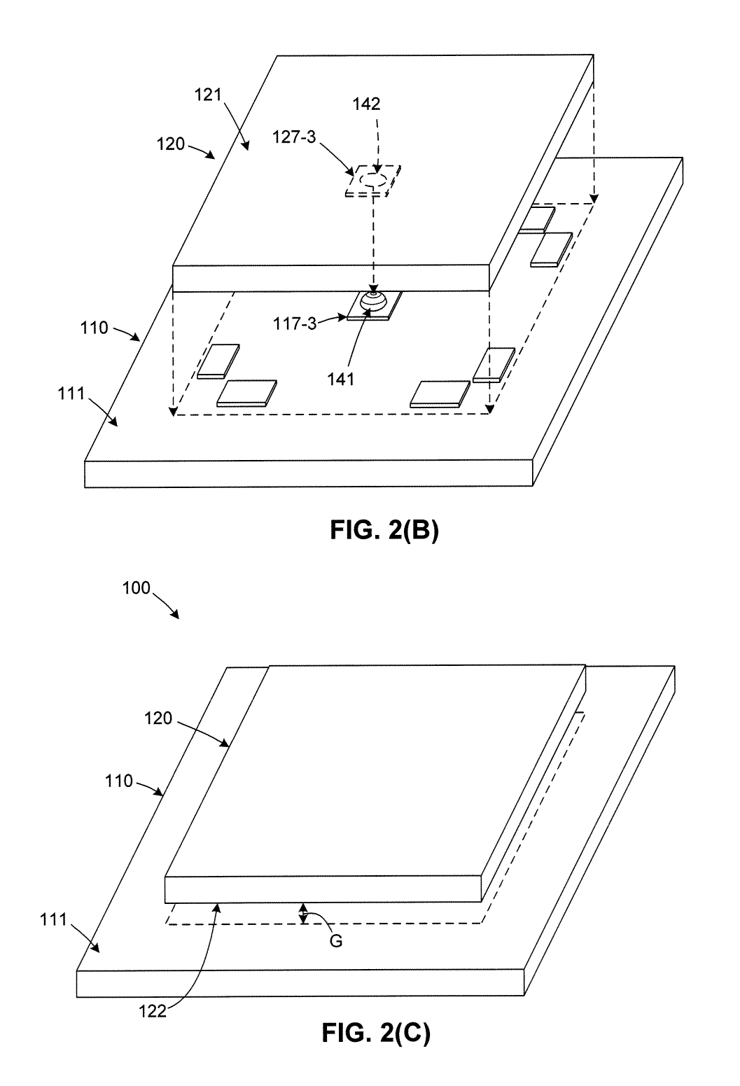

FIGS. 2(A) to 2(C) illustrate a basic package assembly process for producing circuit assembly 100 (FIG. 1) according to another embodiment of the present invention.

FIG. 2(A) shows IC die 120 disposed over support structure 110 with processed surface 122 facing upward. According to a first aspect, IC die 120 is fabricated to include multiple micro-springs 130 (including micro-springs 130-1 and 130-2 of FIG. 1(A)) that are disposed in a peripheral area P on processed surface 122 and released prior to assembly onto support structure 110. In one embodiment, micro-springs 130 are formed using a self-bending spring metal that is deposited as a stress-engineered film that is then patterned to form spring material islands (flat structures) in which its lowermost portions (i.e., the deposited material adjacent to processed surface 122) has a lower internal tensile stress than its upper portions (i.e., the horizontal layers located furthest from processed surface 122), thereby causing the stress-engineered metal film to have internal stress variations that cause a narrow “finger” portion of the spring metal island to bend upward away from IC die 120 during the subsequent release process. Methods for generating such internal stress variations in stress-engineered metal films are taught, for example, in U.S. Pat. No. 3,842,189 (depositing two metals having different internal stresses) and U.S. Pat. No. 5,613,861 (e.g., single metal sputtered while varying process parameters), both of which being incorporated herein by reference. In one embodiment, a titanium (Ti) release material layer is deposited on processed surface 122, then a stress-engineered metal film includes one or more of molybdenum (Mo), a “moly-chrome” alloy (MoCr), tungsten (W), a titanium-tungsten alloy (Ti:W), chromium (Cr), copper (Cu), nickel (Ni) and a nickel-zirconium alloy (NiZr) are either sputter deposited or plated over the release material. An optional passivation metal layer (not shown; e.g., gold (Au), platinum (Pt), palladium (Pd), or rhodium (Rh)) may be deposited on the upper surface of the stress-engineered metal film to act as a seed material for the subsequent plating process if the stress-engineered metal film does not serve as a good base metal. The passivation metal layer may also be provided to improve contact resistance in the completed spring structure. In an alternative embodiment, a nickel (Ni), copper (Cu) or nickel-zirconium (NiZr) film may be formed that can be directly plated without a seed layer. If electroless plating is used, the deposition of the electrode layer can be skipped. In yet another alternative embodiment, the self-bending spring material may be one or more of a bimorph/bimetallic compound (e.g., metal1/metal2, silicon/metal, silicon oxide/metal, silicon/silicon nitride) that are fabricated according to known techniques.

According to a second aspect of the assembly shown in FIG. 2(A), at least one of IC die 120 and support structure 110 are processed to include a solder structure (e.g., a solder bump, solder ball, solder paste pad, etc.) formed on an associated “dummy” contact pad. Referring again to FIG. 2(A), solder structure 146 is formed on support contact pad 117-3, and solder structure 147 is formed on device contact pad 127-3. In a preferred embodiment these solder structures are formed using existing techniques and equipment.

As indicated by the dashed-line arrows in FIG. 2(A), IC die 120 is “flipped” (turned upside down such that processed surface 122 faces upper surface 111 of support structure) and oriented such that the tips of micro-springs 130 are aligned with associated device contact pads (e.g., such that micro-springs 130-1 and 130-2 align with device contact pads 117-1 and 117-2, respectively), and such that solder structures 146 and 147 are also aligned with each other.

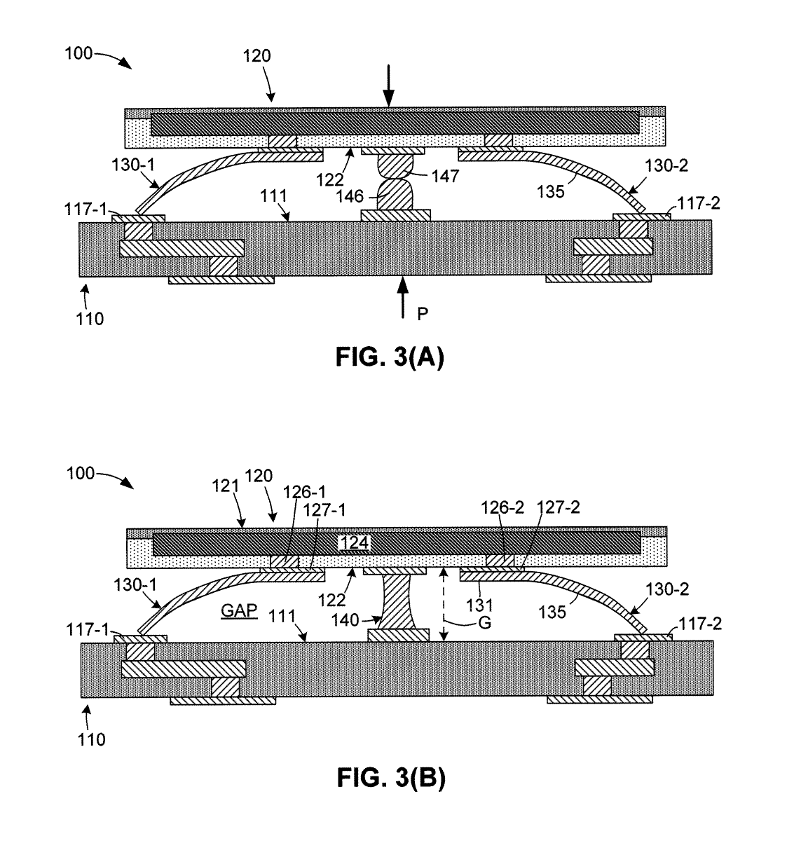

As indicated in FIGS. 2(B) and 3(A), IC die 120 is then lowered onto support substrate 110 such that the tips of micro-springs 130 abut associated device contact pads (e.g., such that micro-springs 130-1 and 130-2 abut device contact pads 117-1 and 117-2, respectively), and such that solder structure 146 abuts solder structure 147. A predetermined pressure (force) P is applied that pushes IC device 120 against support structure 110 such that all of the micro-springs undergo resilient bending (deflection), which produces reliable electrical contact between the micro-springs and associated contact pads. The solder structure contact made during this initial assembly step (e.g., solder bumps into screen printed solder paste) provides adhesion and stability needed for the assembly to pass through the solder reflow step in the desired contact pressure.

As indicated in FIGS. 2(C) and 3(B), IC die 120 is then mechanically attached to support structure 110 by way of standard solder reflow. That is, the assembly is heated to a temperature that causes solder/paste solder structures formed on IC die 120 and support structure 110 to melt and fuse together, thereby forming solder-based interconnect structure 140. Subsequent cooling of the assembly causes solder-based interconnect structure 140 to form a rigid structure that mechanically connects IC die 120 to support structure 110 by way of “dummy” contact pads 117-3 and 127-3. In addition, electrical connections between IC die 120 and support structure 110 by way of the multiple micro-springs (e.g., as shown in FIG. 3(B), electrical connection between circuit 124 and support structure 110 is formed by way of interconnects 126-1/126-2, device contact pads 127-1/127-2, micro-springs 130-1/130-2, and support contact pads 117-1/117-2, respectively). As indicated in both FIGS. 2(C) and 3(B), solder-based interconnect structure 140 maintains processed (lower) surface 122 of IC die 120 at a desired gap distance G from upper surface 111 of IC device 110, where gap distance G set such that the tip portions of all micro-springs (e.g., springs 130-1 and 130-2) apply a pressing force against its associated “functional” support contact pad (e.g., contact pads 117-1 and 117-2).

The method presented above eliminates or minimizes the use of adhesives to provide a packaging approach that is primarily inorganic, which is desirable in military, DoD and high-rel commercial applications. That is, the gap region GAP between IC die 120 and support structure 110 is preferably air-filled or filled with an inert material. However, in some applications the mechanical connection between IC die 120 and support structure 110 may be enhanced by inserting an adhesive into gap region GAP. The method is performed using standard microelectronics, assembly and solder reflow equipment in order to minimize changes to existing assembly lines.

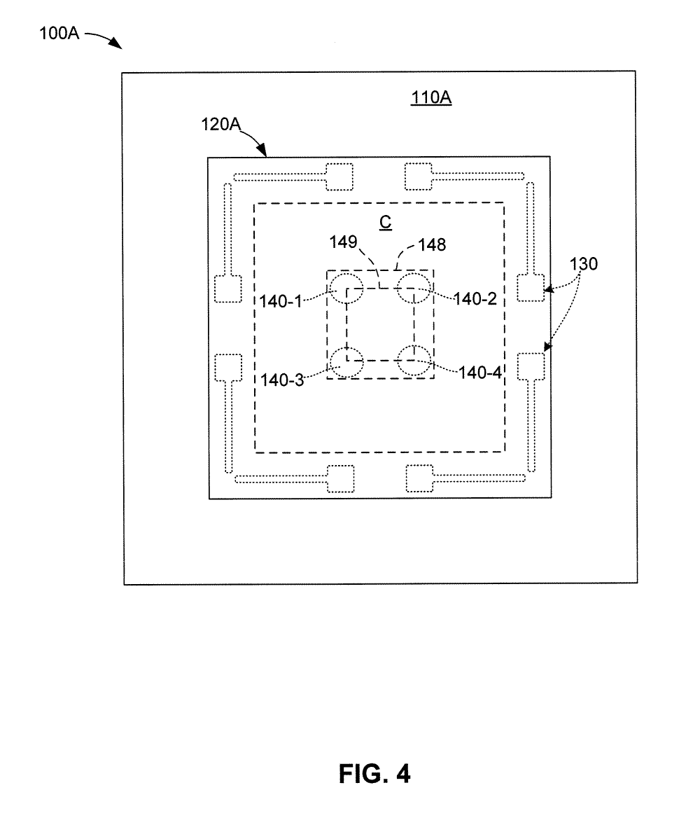

FIG. 4 is a top view showing a packaged semiconductor device (circuit assembly) 100A according to an alternative embodiment of the present invention. Device 100A includes a support structure 110A, an IC die 120A, and micro-springs 130 that are formed and assembled in a manner substantially identical to that described above, but differs in that it includes four solder-based interconnect structures 140-1 to 140-4 connected between associated “dummy” contact pads disposed on support structure 110A and IC die 120A such that IC die 120A is rigidly mechanically secured to support structure 110A by solder-based interconnect structures 140-1 to 140-4. In order to minimize the effects of TCE mismatch, solder-based interconnect structures 140-1 to 140-4 are preferably located close to each other and clustered in one area of the total component/chip area (e.g., disposed inside a region 148 equal to or less than 25% of a total area IC die 120). Although region 148 is indicated in FIG. 4 as being centrally located, region 148 need not be centrally located (i.e., region 148 may be located in one of the corner sections of central region C).

In one embodiment the “dummy” contact pads to which solder-based interconnect structures 140-1 to 140-4 are attached, which are similar to contact pads 117-3 and 127-3 (described above with reference to FIG. 1(A)), are sized to facilitate maximum capillary forces that act in the molten solder to pull the associated components together (i.e. maximum perimeter length within some areal constraints). The capillary forces pulling the two elements together are proportional to the circumference of the solder “pool” once it is molten. A contact pad with a “crenelated or wavy” edge would have a greater circumference to area ratio and hence a higher attractive force, and since the pool edge is defined by the metal contact pads, this perimeter can be lithography defined.

According to another embodiment, solder-based interconnect structures 140-1 to 140-4 are located around a perimeter 149 of a “hot spot” (i.e., a localized area of higher than average temperature) of IC die 120A. Because solder acts a good thermal conductor, solder-based interconnect structures 140-1 to 140-4 are designed and laid out explicitly to overlay the parts of IC die 120A which generate the most heat (e.g., the area delineated by perimeter 149), where solder-based interconnect structures 140-1 to 140-4 act as pathways to remove heat from device 100A, e.g., through copper-filled through board vias (not shown) provided on support structure 110A. Expanding on this heat-removal function, solder-based interconnect structures 140-1 to 140-4 are designed to form a perimeter around the hot spot, and in this embodiment include a solder material component having a higher thermal conductivity (e.g. a much lower melting point material such as indium) that is either deposited prior to reflow, or capillaried in subsequent to reflow to provide superior heat management.

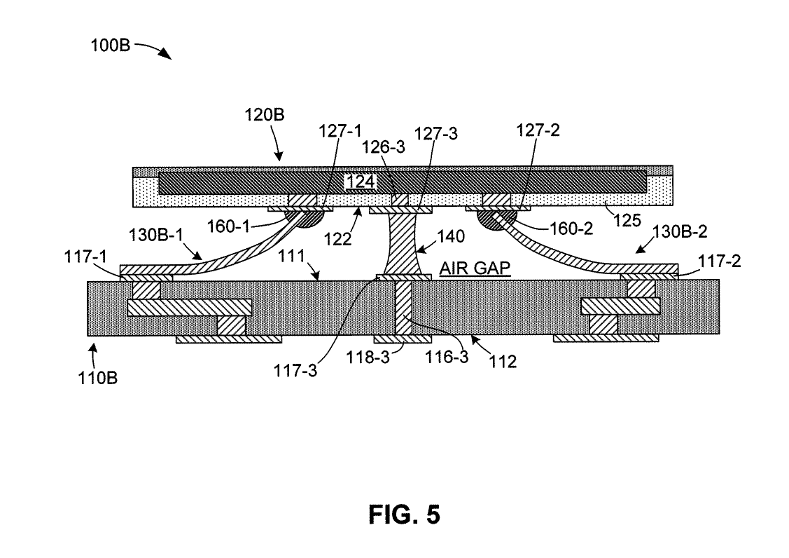

As described above, each micro-spring is an etched interconnect structure that attaches on one end to a carrier device (e.g., IC die 120 in the first embodiment) and on the other end to a mating device (e.g., support structure 110), and serves as an improvement to both existing micro-spring and solder-type interconnections between a chip package and a carrier/substrate/interconnect board. In alternative embodiments the role of host substrate for the micro-springs is performed by the support substrate. For example, as illustrated by packaged semiconductor device (circuit assembly) 100B in FIG. 5, in an alternative embodiment micro-springs 130B-1 and 130B-2 are fabricated on package substrate 110B (i.e., instead of on IC device 120B), whereby the anchor ends of micro-springs 130B-1 and 130B-2 are fixedly attached to support contact pads 117-1 and 117-2 on upper surface 111B of support structure 110B, and the tip ends are in nonattached contact with contact pad 127B-1 and 127B-2 on processed surface 122 of IC die 120B. Optional stand-off structures (not shown) are provided that extend between upper surface 111B and processed surface 122 to maintain the optimal air-gap distance between substrate 110B and IC device 120B. Device 100B is otherwise similar to the embodiments described above in that IC die 120B is secured to support substrate 110B by way of one or more solder-based interconnect structures 140.

Although the present invention has been described with respect to certain specific embodiments, it will be clear to those skilled in the art that the inventive features of the present invention are applicable to other embodiments as well, all of which are intended to fall within the scope of the present invention. For example, as indicated in FIG. 5, instead of being formed between “dummy” contact pads, in one embodiment the (second) device and support contact pads attached to solder-based interconnect structure 140 are electrically connected to respective circuit and interconnect structures (e.g., support contact pad 117-3 is connected lower contact pad 118-3 by way of via-type interconnect structure 116-3, and device contact pad 127-3 is connected to circuit 124 by way of conductor 126-3 extending through passivation layer 125), whereby solder-based interconnect structure 140 serves to transmit an electrical signal (e.g., a ground (zero volt) source utilized by circuit 124). Further, although the invention has been described above with reference to micro-springs having nonattached contact with associated contact pads, the tip ends of the micro-springs may be secured by way of solder using existing techniques (e.g., as shown in FIG. 5, the tips of micro-springs 130B-1 and 130B-2 are respectively attached to device contact pads 127-1 and 127-2 by way of solder structures 160-1 and 160-2. Moreover, although the present invention is described with reference to the formation of a semiconductor package-type structure, the assembly method described herein may be utilized to secure other components or elements (e.g., LED elements) to a support structure, or one or more IC dies in a multi-level packaging arrangement or IC devices (i.e., packaged IC dies) to large PCBs in system-level settings.

1. A circuit assembly comprising:
a support structure including a first support contact pad and a second support contact pad disposed on an upper surface thereof, said first support contact pad being electrically connected to at least one conductor disposed on said support structure;
a device mounted on the support structure such that a lower surface of the device faces the upper surface of the support structure, the device including first and second device contact pads that are disposed on the lower surface, said first device contact pads being electrically connected to at least one conductive structure disposed on said device;
a curved micro-spring disposed in a gap region defined between the upper surface of the support structure and the lower surface of the device, the micro-spring including a first end that is electrically connected to the first device contact pad, a second end that is electrically connected to the first support contact pad, and a curved body portion extending between the first and second ends; and
a solder-based interconnect structure having a first end portion connected to the second support contact pad, a second end portion connected to the second device contact pad, and a body portion extending between the first and second end portions such that the device is rigidly mechanically secured to the support structure by said solder-based interconnect structure.

2. The circuit assembly according to claim 1, wherein the support structure comprises a non-conductive material and includes a plurality of conductors disposed on said non-conductive material, and wherein the second support contact pad is disposed on said non-conductive material such that the second support contact pad is electrically isolated from said plurality of conductors.

3. The circuit assembly according to claim 1, wherein the device comprises an integrated circuit (IC) die including a semiconductor chip having a processed surface and an opposing unprocessed surface, said at least one conductive structure being disposed on the processed surface, said IC die further including a passivation layer formed on said semiconductor chip over said at least one conductive structure, wherein the second device contact pad is disposed on said passivation layer such that the second device contact pad is electrically isolated from said at least one conductive structure.

4. The circuit assembly according to claim 1, wherein said at least one solder-based interconnect structure comprises a lead-free solder material including indium.

5. The circuit assembly according to claim 1, wherein said micro-spring comprises one of molybdenum (Mo), molybdenum-chromium (MoCr) alloy, tungsten (W), a titanium-tungsten alloy (Ti:W), chromium (Cr), copper (Cu), nickel (Ni) and nickel-zirconium alloy (NiZr)).

6. The circuit assembly according to claim 1, wherein the first end of said micro-spring is fixedly attached to the lower surface of the device, and the second end of said micro-spring is in nonattached contact with said first support contact pad.

7. The circuit assembly according to claim 1,
wherein said device comprises a substantially four-sided peripheral edge formed by first, second, third and fourth side edges,
wherein said micro-spring is disposed in a peripheral area adjacent to one of said first, second, third and fourth side edges, and
wherein said solder-based interconnect structure is disposed in a central area that is surrounded by said peripheral area.

8. The circuit assembly according to claim 1, further comprising a plurality of solder-based interconnect structures, each of the plurality of solder-based interconnect structures having a first end portion connected to an associated second support contact pad, a second end portion connected to an associated second device contact pad, and a body portion extending between the first and second end portions such that the IC device is rigidly mechanically secured to the support structure by said plurality of solder-based interconnect structures.

9. The circuit assembly according to claim 8, wherein all of said plurality of solder-based interconnect structures are disposed in a central area of said IC die.

10. The circuit assembly according to claim 8, wherein all of said plurality of solder-based interconnect structures are disposed inside a region equal to or less than 25% of a total area of said IC die.

11. The circuit assembly according to claim 1, wherein the first end of said micro-spring is fixedly attached to the upper surface of the support structure, and the second end of said micro-spring is in nonattached contact with said first device contact pad.

12. The circuit assembly according to claim 1, wherein the first end of said micro-spring is fixedly attached to the lower surface of the device, and the second end of said micro-spring is in nonattached contact with said first device contact pad.

13. A packaged semiconductor device comprising:
a package base substrate including a first and second base contact pads disposed on an upper surface thereof;
an integrated circuit (IC) die having an processed surface including first and second die contact pads, said first die contact pad being electrically connected to an integrated circuit fabricated on said IC die;
a plurality of curved micro-springs disposed between the package base substrate and the IC die such that a first end of each micro-spring is electrically connected to an associated said first base contact pad and a second end of each said micro-spring is electrically connected to an associated first die contact pad, wherein each said micro-spring includes a curved body portion extending between the first and second ends such that an air gap region is defined between the upper surface of the package base substrate and the processed surface of the IC die; and
a plurality of solder-based interconnect structures, each said solder-based interconnect structure having a first end portion connected to an associated second base contact pad, a second end portion connected to an associated second die contact pad, and a body portion extending between the first and second end portions such that the IC die is rigidly mechanically secured to the package base substrate by said plurality of solder-based interconnect structures.

14. A method for electrically and mechanically securing a device to a support structure, the support structure having first and second support contact pads disposed on an upper surface thereof, and the device having a processed surface including a first device contact pad and a second device contact pad, said first die contact pad being electrically connected to a circuit disposed on said device, wherein a solder structure is disposed on at least one of the second device contact pad, the method comprising:
mounting the device onto the support structure such that a first end of a micro-spring is electrically connected to the first support contact pad and a second end of the micro-spring is electrically connected to the first device contact pad, and such that a curved body portion said micro-spring extending between the first and second ends is disposed in an air gap region defined between the upper surface of the support structure and the processed surface of the device; and
mechanically attaching the device to the support structure by causing the solder structure to form a solder-based interconnect structure having a first end portion connected to the second support contact pad, a second end portion connected to the second device contact pad, and a body portion extending between the first and second end portions such that the device is rigidly mechanically secured to the support structure by said solder-based interconnect structure.

15. The method of claim 14, further comprising forming a solder bump on a first one of the second device contact pad and the second support contact pad, and forming a solder paste pad on a second one of the second device contact pad and the second support contact pad, and
wherein mounting comprises aligning the second device contact pad with the second support contact pad such that the solder bump contacts the solder paste pad.

16. The method of claim 15, wherein mechanically attaching the device to the support structure comprises performing a solder reflow process.

17. The method of claim 14, wherein the first end of said micro-spring is fixedly attached to the processed surface of the device, and wherein mounting the device comprises causing the second end of said micro-spring to make nonattached contact with said second support contact pad.

18. The method of claim 14, wherein the first end of said micro-spring is fixedly attached to the upper surface of the support structure, and wherein mounting the device comprises causing the second end of said micro-spring to make nonattached contact with said second device contact pad.

19. The method of claim 18, further comprising mechanically attaching the second end of said micro-spring to said second device contact pad by way of solder.
